(19) United States
(12) Patent Application Publication
(10) Pub. No.: US 2006/0255450 A1
(43) Pub. Date: Nov. 16, 2006

(54) Devices incorporating carbon nanotube thermal pads

(75) Inventors: Lawrence S. Pan, Los Gatos, CA (US); Srinivas Rao, Saratoga, CA (US); Jim Protsenko, San Jose, CA (US)

Correspondence Address: CARR & FERRELL LLP, 2200 GENG ROAD, PALO ALTO, CA, 94303, US

(73) Assignee: Molecular Nanosystems, Inc.

(21) Appl. No.: 11/433,311

(22) Filed: May 11, 2006

Related U.S. Application Data
(60) Provisional application No. 60/680,262, filed on May 11, 2005.
(60) Provisional application No. 60/691,673, filed on Jun. 17, 2005.
(60) Provisional application No. 60/709,611, filed on Aug. 19, 2005.

(51) Int. Cl. H01L 23/34

(52) U.S. Cl. 257/712

(57) ABSTRACT

Devices and methods for their manufacture are provided. The devices, such as packaged semiconductors, include thermal pads of vertically aligned carbon nanotubes to transport heat from a heat source such as a semiconductor die, to or between thermal management aids such as a heat spreader or heat sink. Some devices include spacers between the heat spreader and the heat sink to protect the thermal pad during assembly. Other devices include thermal pads that have surface layers matched by composition to the surfaces of the opposing surfaces, thus silicon on one side and a metal on the other. In some devices, the ends of the carbon nanotubes extend into the surface of the thermal management aid. Methods for bonding the thermal pads include bonding surface layers, as well as exposed carbon nanotubes, to opposing surfaces.

### CROSS-REFERENCE TO RELATED APPLICATIONS

This application claims the benefit of U.S. Provisional Patent Application No. 60/680,262 filed on May 11, 2005 and entitled “Carbon Nanotube-Based Thermal Pad,” U.S. Provisional Patent Application No. 60/691,673 filed on Jun. 17, 2005 and entitled “Carbon Nanotube-Based Thermal Pad,” and U.S. Provisional Patent Application No. 60/709,611 filed on Aug. 19, 2005 and entitled “Carbon Nanotube Based Interface Materials for Heat Dissipation Applications,” each of which is incorporated herein by reference in its entirety. This application is related to U.S. Non-Provisional Patent Application Ser. No. ______ filed on even date herewith and entitled “Methods for Producing Free-Standing Carbon Nanotube Thermal Pads” (attorney docket number PA3336US). This application is also related to U.S. Non-Provisional Patent Application Ser. No. ______ filed on even date herewith and entitled “Methods for Forming Carbon Nanotube Thermal Pads” (attorney docket number PA3283US). This application is further related to U.S. Non-Provisional Patent Application Ser. No. ______ filed on even date herewith and entitled “Carbon Nanotube Thermal Pads” (attorney docket number PA3396US).

### STATEMENT REGARDING FEDERALLY SPONSORED RESEARCH OR DEVELOPMENT

This invention was made with United States Government support under Cooperative Agreement No. 70NANB2H3030 awarded by the Department of Commerce's National Institute of Standards and Technology. The United States has certain rights in the invention.

### BACKGROUND OF THE INVENTION

1. Field of the Invention

The present invention relates generally to the field of semiconductor packaging and more particularly to methods for forming structures that employ carbon nanotubes for thermal dissipation.

2. Description of the Prior Art

A carbon nanotube is a molecule composed of carbon atoms arranged in the shape of a cylinder. Carbon nanotubes are very narrow, on the order of nanometers in diameter, but can be produced with lengths on the order of hundreds of microns. The unique structural, mechanical, and electrical properties of carbon nanotubes make them potentially useful in electrical, mechanical, and electromechanical devices. In particular, carbon nanotubes possess both high electrical and thermal conductivities in the direction of the longitudinal axis of the cylinder. For example, thermal conductivities of individual carbon nanotubes of 3000 W/m-° K and higher at room temperature have been reported.

The high thermal conductivity of carbon nanotubes makes them very attractive materials for use in applications involving heat dissipation. For example, in the semiconductor industry, devices that consume large amounts of power typically produce large amounts of heat. Following Moore's Law, chip integration combined with die size reduction results in an ever increasing need for managing power density. The heat must be efficiently dissipated to prevent these devices from overheating and failing. Presently, such devices are coupled to large heat sinks, often through the use of a heat spreader. Additionally, to allow for differences in coefficients of thermal expansion between the various components and to compensate for surface irregularities, thermal interface materials such as thermal greases are used between the heat spreader and both the device and the heat sink. However, thermal greases are both messy and require additional packaging, such as spring clips or mounting hardware, to keep the assembly together, and thermal greases have relatively low thermal conductivities.

Therefore, what is needed are better methods for attaching heat sinks, sources, and spreaders that provides both mechanical integrity and improved thermal conductivity.

### SUMMARY

An exemplary electronic device comprises a semiconductor die, a heat sink, and a heat spreader therebetween. The device also includes a first thermal pad disposed between the semiconductor die and the heat spreader aid, a second thermal pad disposed between the heat sink and the heat spreader, and a spacer disposed between the heat sink and the heat spreader. The device can also comprise a substrate beneath the semiconductor die and a spacer between the substrate and the heat sink. In some embodiments the spacer is integral with the heat spreader or the heat sink. Where the spacer is integral with one of the heat spreader or the heat sink, the other of the two can include a recess that engages the spacer.

Another exemplary electronic device comprises a heat source, a thermal management aid such as a heat sink or heat spreader, and a thermal pad disposed between the heat source and the thermal management aid. The thermal pad includes a sheet of vertically aligned carbon nanotubes, a silicon layer between the sheet and the heat source, and a metal layer, such as copper, between the sheet and the thermal management aid. The interstitial space between the carbon nanotubes of the sheet can be substantially unfilled in some embodiments. In some embodiments, the silicon layer and the heat source can be joined together by van der Waals attractions. The device can also comprise an adhesive layer between the metal layer and the thermal management aid, and in some of these embodiments the adhesive layer can be electrically insulating.

Still another exemplary electronic device comprises a semiconductor die formed of a semiconducting material, a thermal management aid, and a thermal pad disposed between the heat source and the thermal management aid. In these embodiments the thermal pad includes a sheet of vertically aligned carbon nanotubes having first and second sides, where the ends of the carbon nanotubes of the first side extend at least partially into the thermal management aid. The thermal pad also comprises a layer between the second side of the sheet and the semiconductor die, the layer also formed of the semiconducting material.

An exemplary mobile device comprises an active component such as an RF amplifier or a digital signal processor, an EMI enclosure, and a thermal pad including a sheet of vertically aligned carbon nanotubes providing thermal communication between the active component and the EMI enclosure.

An exemplary method for making an electronic device comprises receiving a thermal pad on a carrier tape from a spool of thermal pads, and bonding the thermal pad between a semiconductor die and a thermal management aid. In these embodiments the thermal pads include an array of generally aligned carbon nanotubes. Bonding the thermal pad can include, for example, plasma etching a surface of the array, dry pressing the thermal pad to the thermal management aid, or anodic bonding of a surface of the thermal pad to either the semiconductor die or the thermal management aid.

Another exemplary method for making an electronic device comprises bonding a first side of a thermal pad to a thermal management aid, the thermal pad including an array of generally aligned carbon nanotubes disposed on a substrate, separating the substrate from a second side of the thermal pad after bonding the first side, and bonding the second side of the thermal pad to a semiconductor die.

### BRIEF DESCRIPTION OF DRAWINGS

FIGS. 1-11 show cross-sectional views of thermal pads according to various exemplary embodiments of the invention. The orders of the layers, from bottom to top, in each of these drawings also serve to illustrate exemplary methods of forming the thermal pads.

FIG. 12 shows a cross-sectional view of a partially completed thermal pad according to an exemplary embodiment of the invention.

FIG. 13 shows a cross-sectional view of the thermal pad of FIG. 12 after an array of vertically aligned carbon nanotubes has been fabricated according to an exemplary embodiment of the invention.

FIG. 14 shows a cross-sectional view of still another thermal pad according to an exemplary embodiment of the invention.

FIG. 15 shows a top view of a portion of a lead frame used as a substrate for forming a thermal pad according to an exemplary embodiment of the invention.

FIG. 16 shows a cross-sectional view of a plurality of lead frames disposed in a tube furnace for carbon nanotube synthesis thereon, according to an exemplary embodiment of the invention.

FIG. 17 shows a cross-sectional view of the lead frames and furnace of FIG. 16 taken along the line 17-17.

FIG. 18 shows an enlarged view of a portion of the cross-sectional view of FIG. 17.

FIG. 19 shows a cross-sectional view of a partially completed thermal pad on a substrate according to an exemplary embodiment of the invention. The order of the layers, from bottom to top, serves to illustrate exemplary methods of forming the thermal pad.

FIG. 20 shows a cross-sectional view of the thermal pad of FIG. 19 after separation from the substrate.

FIG. 21 shows a cross-sectional view of a partially completed thermal pad on a substrate according to another exemplary embodiment of the invention. The order of the layers, from bottom to top, serves to illustrate further exemplary methods of forming the thermal pad.

FIG. 22 shows a cross-sectional view of the thermal pad of FIG. 21 after separation from the substrate.

FIG. 23 shows a top view of a partially completed thermal pad formed on a semiconductor wafer and the same wafer after dicing into coupons, according to an exemplary embodiment of the invention.

FIG. 24 shows a cross-sectional view of a partially completed thermal pad on a substrate according to still another exemplary embodiment of the invention. The order of the layers, from bottom to top, serves to illustrate further exemplary methods of forming the thermal pad.

FIG. 25 shows a cross-sectional view of the thermal pad of FIG. 24 after separation from the substrate.

FIGS. 26-29 show cross-sectional views of devices including a thermal pad according to exemplary embodiments of the invention.

FIG. 30 shows an exemplary spool of thermal pads for use in automated tape bonding according to an embodiment of the invention.

FIGS. 31 and 32 are cross-sectional views of mobile consumer products including thermal pads according to exemplary embodiments of the invention.

### DETAILED DESCRIPTION OF THE INVENTION

The present invention provides devices, and methods of making the devices, that include carbon nanotube-based thermal pads, both free-standing and supported on a thin substrate such as a foil, a thin metal sheet, or the surface of a component of a device. Each thermal pad is characterized by an array of generally aligned carbon nanotubes, forming a sheet, and having a direction of alignment that is essentially perpendicular to the major surfaces of the thermal pad. The alignment of the nanotubes allows the array to provide excellent thermal conduction in the direction of alignment. Accordingly, a thermal pad between a heat source and a heat sink provides a thermally conductive interface therebetween.

Some thermal pads are characterized by at least one, and in some instances, two very smooth surfaces. A thermal pad with a sufficiently smooth surface can adhere to another very smooth surface, such as the backside surface of semiconductor die, much like two microscope slides will adhere to each other. Surfaces of thermal pads, whether very smooth or not, can also be attached to an opposing surface with a metal layer, for example with solder, indium, or silver. Advantageously, some thermal pads are also characterized by a degree of flexibility and pliability. This can make it easier to work with the thermal pads in assembly operations and allows the thermal pads to conform to opposing surfaces that are curved or irregular.

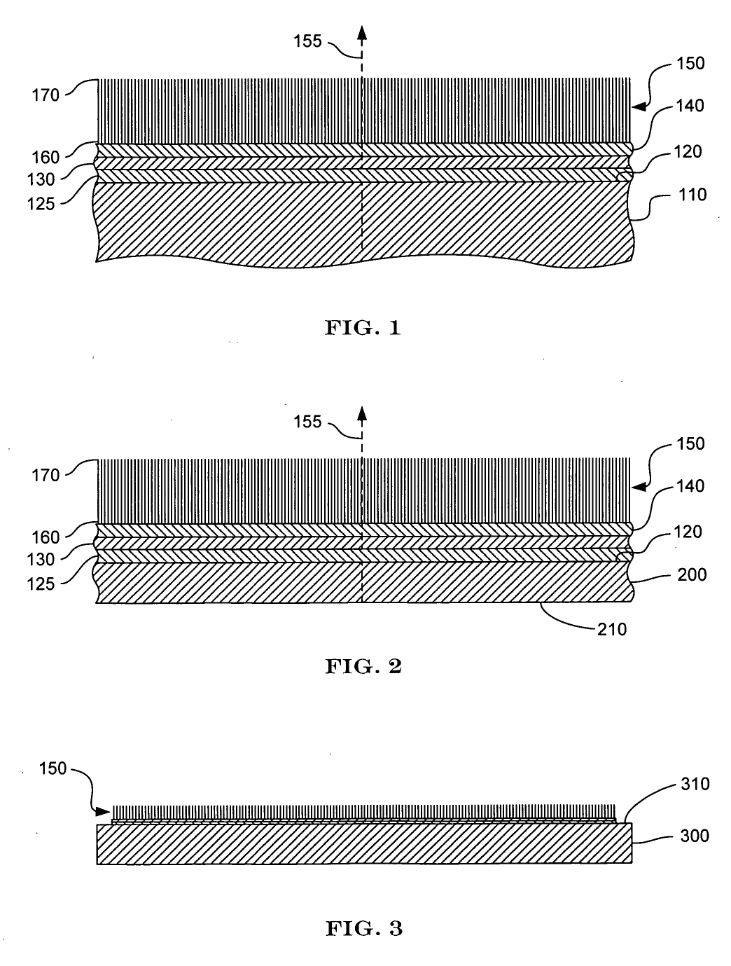

FIG. 1 illustrates an exemplary method of forming a thermal pad. In the exemplary method a substrate 110 with a generally planar surface 120 is initially provided. Various examples of suitable substrates 110 are described below. Next, an optional barrier layer 125 is formed on the planar surface 120. The purpose of the barrier layer 125 is to prevent diffusion between the substrate 110 and a subsequently deposited catalyst layer. Preventing such diffusion is desirable in those embodiments where the substrate 110 includes one or more elements that can poison the catalyst and prevent nanotube growth. Examples of elements that are known to poison nanotube catalysis include nickel, iron, cobalt, molybdenum, and tungsten. Other substrates, such as silicon, are not known to poison nanotube catalysis and may not therefore require the barrier layer 125. An example of a suitable barrier layer 125 is a sputtered film of aluminum oxide with a thickness of at least 50 Å, and more preferably 100 Å. An appropriate thickness for the barrier layer 125 will depend both on the permeability of the selected material to the elements to be impeded, and also on the roughness of the planar surface 120, as rougher finishes require thicker barrier layers 125.

An optional interface layer 130 is formed over the planar surface 120, and over the barrier layer 125, if present. The interface layer 130 is provided, where needed, to improve the subsequent catalyst layer which, in turn, provides for higher quality nanotubes characterized by higher wall crystallinities and fewer defects. In some embodiments, a single layer can serve as both the barrier layer 125 and the interface layer 130. Again, a sputtered film of aluminum oxide with a thickness of at least 50 Å, and more preferably 100 Å can be a suitable interface layer 130. Another suitable interface layer 130 includes silicon dioxide. It should be noted that too thick of an interface layer 130 can lead to cracking during thermal cycling due to mismatches in coefficients of thermal expansion between the interface layer 130 and the layer beneath.

Next, a catalyst layer 140 is formed. The catalyst layer 140 can be formed either directly on the planar surface 120 of the substrate 110, on the barrier layer 125, or on the interface layer 130, depending on the various materials chosen for the substrate 110 and the catalyst layer 140. After the catalyst layer 140 has been formed, an array 150 of carbon nanotubes is formed on the catalyst layer 140. The array 150 is formed such that the carbon nanotubes are generally aligned in a direction 155 perpendicular to the planar surface 120. The array 150 includes a first end 160 attached to the catalyst layer 140 and a second end 170 opposite the first end 160. Depending on the growth conditions and choice of catalyst, the carbon nanotubes can be single-walled or multi-walled. The density, diameter, length, and crystallinity of the carbon nanotubes can also be varied to suit various applications.

One general method for achieving carbon nanotube growth is to heat the catalyst layer 140 in the presence of a carbon-bearing gas. Examples of suitable catalysts and process conditions are taught, for example, by Erik T. Thostenson et al. in “Advances in the Science and Technology of Carbon Nanotubes and their Composites: a Review,” Composites Science and Technology 61 (2001) 1899-1912, and by Hongjie Dai in “Carbon Nanotubes: Opportunities and Challenges,” Surface Science 500 (2002) 218-241. It will be appreciated, however, that the present invention does not require preparing the carbon nanotubes by the catalysis methods of either of these references, and any method that can produce generally aligned carbon nanotubes extending from a surface is acceptable.

FIGS. 2-5 illustrate the method set forth with respect to FIG. 1 as applied to specific substrates. In FIG. 2 a substrate 200 represents either a thin substrate or a foil. Both a foil and a thin substrate are characterized by the planar surface 120 and an opposing planar surface 210. In some embodiments, the planar surface 210 has an optically smooth finish. The distinction between a foil and a thin substrate is that the thin substrate is self-supporting while the foil is not. Thus, a foil should be secured to a supporting structure such as a pedestal or a frame during processing, while a thin substrate need not be secured. Copper and silver foils are examples of suitable foils. Suitable thin substrates include polished metal blanks and semiconductor wafers. For example, a 4″ single-crystal silicon wafer can be thinned by conventional backside thinning processes, like grinding followed by chemical mechanical polishing (CMP), to a thickness of 500μ, 300μ, 200μ, 25μ or thinner.

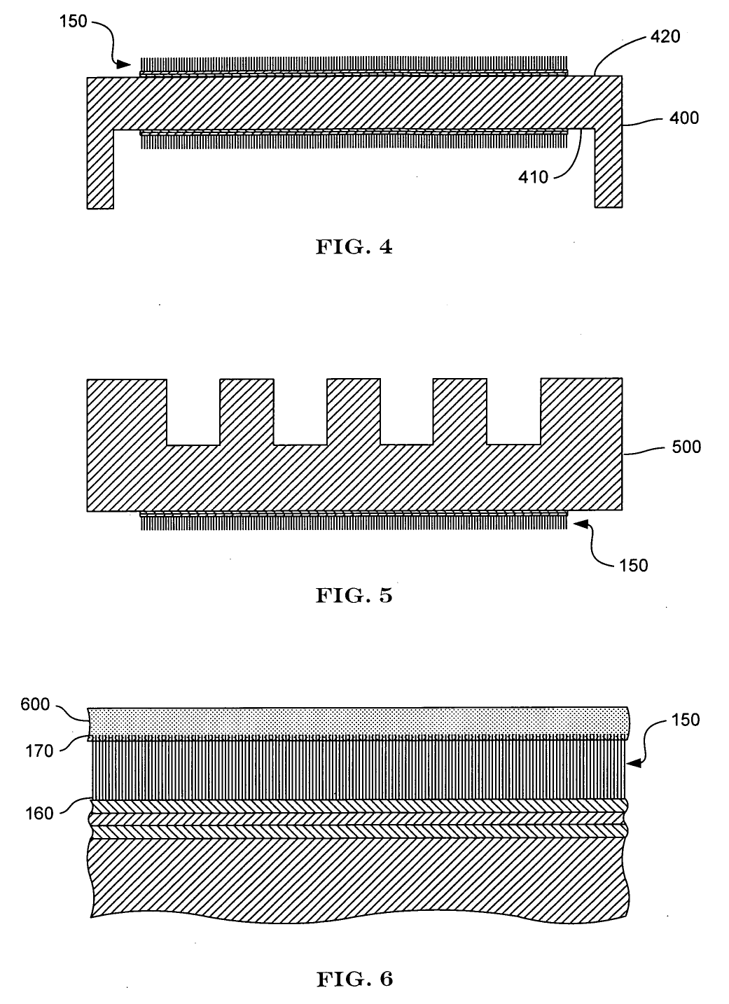

In FIG. 3 a semiconductor die 300 manufactured from a silicon wafer, for example, provides the substrate. In this example, the method is used to grow the array 150 on a backside 310 of the semiconductor die 300. A heat spreader 400 used to distribute heat from a semiconductor die to a heat sink in a semiconductor package provides the substrate in FIG. 4. As shown, the array 150 can be grown by the method on either the surface 410 that faces the semiconductor die, or on the surface 420 that faces the heat sink, or both. The array 150 can also be grown on a heat sink 500, as illustrated by FIG. 5.

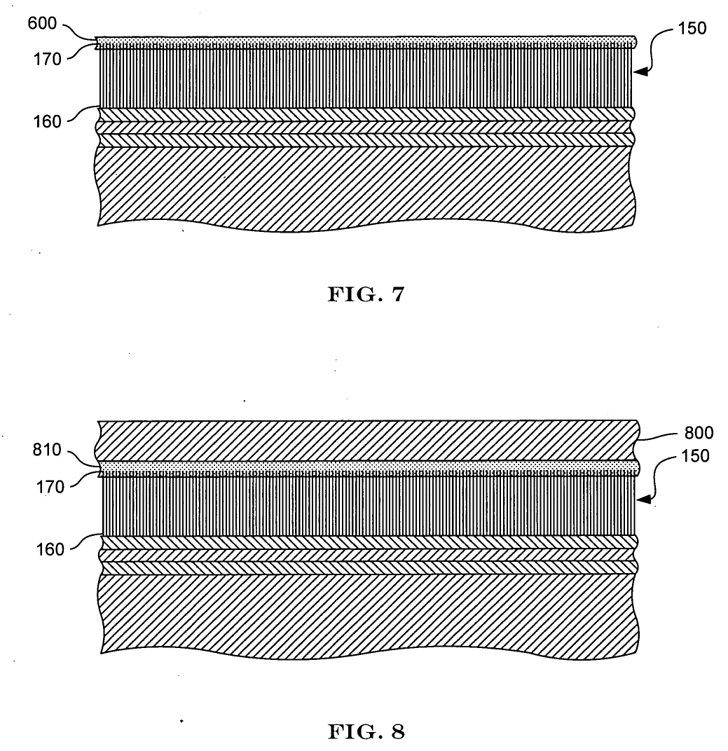

FIGS. 6 and 7 illustrate exemplary further steps to the method of FIG. 1. In FIG. 6 a metal layer 600 is formed on the second end 170 of the array 150 so that the carbon nanotubes extend partially into the metal layer 600. A suitable metal for the metal layer 600 is copper. The metal layer 600 can be formed, for instance, by sputtering, evaporation, or electroplating. It should be noted that the metal layer 600 is not meant to infiltrate the entire array 150 but only to encapsulate the very ends of the carbon nanotubes and to extend a short distance above the second end 170. An appropriate thickness for the metal layer 600 will depend on the density of carbon nanotubes in the array 150 and the variation in their heights, but a minimum thickness for the metal layer 800 is on the order of 200 Å.

In some embodiments, forming the metal layer 600 includes applying a conformal coating to the ends of the carbon nanotubes with a wetting layer of a metal that promotes improved wetting of the metal layer 600 to the carbon nanotubes. Suitable wetting layer materials include palladium, chromium, titanium, vanadium, hafnium, niobium, tantalum, magnesium, tungsten, cobalt, zirconium, and various alloys of the listed metals. The wetting layer can be further coated by a thin protective layer, such as of gold, to prevent oxidation of the wetting layer. The wetting and protection layers may be achieved by evaporation, sputtering, or electroplating, for example. It should be noted that these conformal coatings merely conform to the ends of the carbon nanotubes and are not continuous films across the second end 170 of the array 150. Wetting and protection layers are described in more detail in U.S. Non-Provisional patent application Ser. No. 11/107,599 filed on Apr. 14, 2005 and titled “Nanotube Surface Coatings for Improved Wettability,” incorporated herein by reference in its entirety.

As shown in FIG. 7, the metal layer 600 can be polished to increase the smoothness of the surface. Polishing the metal layer 600 can comprise chemical mechanical polishing (CMP) which also serves to planarize the surface. Copper is a good choice for the metal layer 600, in those embodiments that include CMP of the metal layer 600 in that CMP of copper has been refined in the semiconductor processing arts. In some embodiments, polishing the metal layer 600 continues until the second end 170 of the array 150 is exposed, while in other embodiments polishing is discontinued before that point is reached, as shown in FIG. 7.

As shown in FIG. 8, instead of forming and polishing a metal layer 600, in other embodiments a thermal pad with a smooth surface is obtained by attaching a foil 800 to the array 150. Attaching the foil 800 can include forming an attachment layer 810 on the second end 170 of the array 150 so that the carbon nanotubes extend partially into the attachment layer 810. Ideally, the attachment layer 810 is formed of a low melting point metal or eutectic alloy such as indium, tin, bismuth, or a solder such as tin-silver, tin-lead, lead-silver, gold-germanium, or tin-antimony. The attachment layer 810 may be formed by evaporation, sputtering, electroplating, or melting a thin sheet of the desired material, for example. As above, in some instances a wetting layer with or without a further protective layer can be applied as a conformal coating on the ends of the carbon nanotubes prior to forming the attachment layer 810.

Copper and silver foils are examples of suitable foils 800. The foil 800 can be joined to the attachment layer 810 by heating the foil 800 while in contact with the attachment layer 810 to briefly melt the attachment layer 810 at the interface. In some embodiments, such as those in which the low melting point metal comprises indium, it can be advantageous to strip the native oxide layer from the attachment layer 810 by cleaning the attachment layer 810 with an acid such as hydrochloric acid prior to attaching the foil 800.

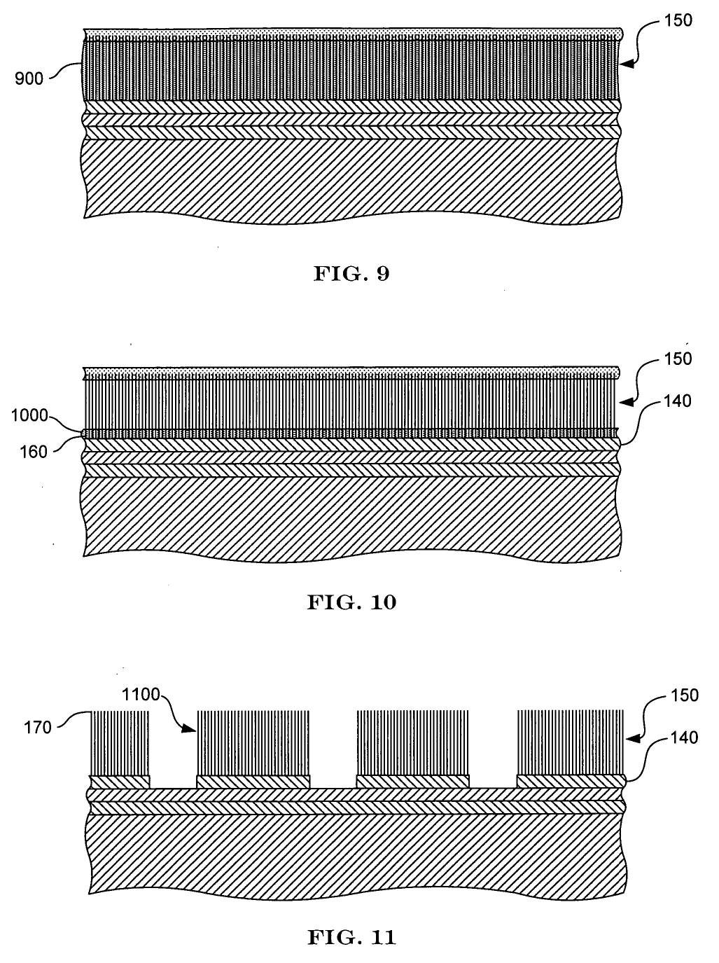

Each of the thermal pads shown in FIGS. 1-8 is characterized by an array 150 of generally aligned carbon nanotubes with empty interstitial space between the carbon nanotubes. The empty interstitial space can be advantageous, in certain situations, as it provides the thermal pads with greater flexibility. In other embodiments, described below with reference to FIGS. 9 and 10, some or all of the interstitial space is filled.

For example, in FIG. 9 the interstitial space is filled by a matrix material 900. Examples of matrix materials include metals and polymers. The interstitial space of the array 150 can be filled by a metal, for example, by electroplating. Injection molding can be used, for instance, to fill the interstitial space of the array 150 with a polymer such as parylene. Polymer injection molding into aligned nanotubes is taught by H. Huang, C. Liu, Y. Wu, and S. Fan in Adv. Mater. 2005, 17, 1652-1656. Both metal and polymers can be useful to provide additional structural support, while metals also provide some additional thermal conductivity.

FIG. 10 shows the interstitial space of the array 150 partially filled with a base metal layer 1000 that surrounds the carbon nanotubes at the first end 160 of the array 150 but otherwise leaves the interstitial space empty. The base metal layer 1000 can be formed of a metal such as copper by electroplating with the catalyst layer 140 serving as an electrode. The base metal layer 1000, like the matrix material 900, is advantageous for further securing the array 150 to the catalyst layer 140. The base metal layer 1000 both provides this advantage while still leaving much of the interstitial space empty for greater flexibility of the thermal pad. It should be understood that the matrix material 900, or base metal layer 1000, can be applied to any of the embodiments taught with respect to FIGS. 1-8.

FIG. 11 illustrates yet another variation on the method of forming a thermal pad. In this example, the catalyst layer 140 is patterned, prior to forming the array 150, so that the carbon nanotubes of the array 150 grow in columns or bundles 1100 as opposed to the prior embodiments where the array 150 forms a continuous sheet of carbon nanotubes. The catalyst layer 140 can be patterned, for example, by conventional masking techniques known to the semiconductor processing arts. Patterning the catalyst layer 140 to produce the bundles 1100 can be useful for those thermal pads that do not have a top layer such as metal layer 600 or foil 800. When the second end 170 of the array 150 of such a thermal pad is joined to a surface, the taller bundles 1100, because of the spaces between the bundles 1100, are able to bend until the shorter bundles 1100 also contact the surface. In a similar manner, bundles 1100 can be beneficial to thermal pads even with a top layer to allow the top layer to deform to match the contour of a mating surface.

It should be noted that a continuous catalyst layer 140, as shown for example in FIG. 1, can be patterned to include a varying composition, thickness, or density of catalyst particles. Examples of such patterned catalyst layers are described in more detail in U.S. Non-Provisional patent application Ser. No. 11/124,005 filed on May 6, 2005 and titled “Growth of Carbon Nanotubes to Join Surfaces,” incorporated herein by reference in its entirety. Providing such patterning can be advantageous to vary aspects of the carbon nanotubes within the array 150 as a function of location. For example, where the thermal pad is intended to provide an interface with a backside of a semiconductor die with a known curvature, such as a convex shape, the heights of the carbon nanotubes can be varied from shorter at the center of the array 150 to longer at the edges. Likewise, a greater density of carbon nanotubes can be grown in areas of the array 150 in order to match the greater density to hot spots on the heat source.

FIGS. 12 and 13 illustrate still another variation on the method of forming a thermal pad. In this example, spacers 1200 are placed over the planar surface 120 of the substrate 110 before the array 150 is formed. In some embodiments, the spacers 1200 are placed on the catalyst layer 140 as shown in FIG. 12. Subsequently, the array 150 is formed, as shown in FIG. 13. Preferably, the array 150 is grown until a height of the array 150 exceeds a height of the spacers 1200. A thermal pad including spacers 1200 can be advantageous during assembly of the thermal pad within a device, package, or other structure. Not only can the spacers 1200 provide an appropriate spacing between two objects such as a heat source and a heat sink, but the spacers 1200 can also prevent damage to the carbon nanotubes of the array 150 by limiting the extent to which the carbon nanotubes can be deformed during handling and assembly. Suitable spacers are described in more detail in U.S. Non-Provisional patent application Ser. No. 11/124,005 noted above.

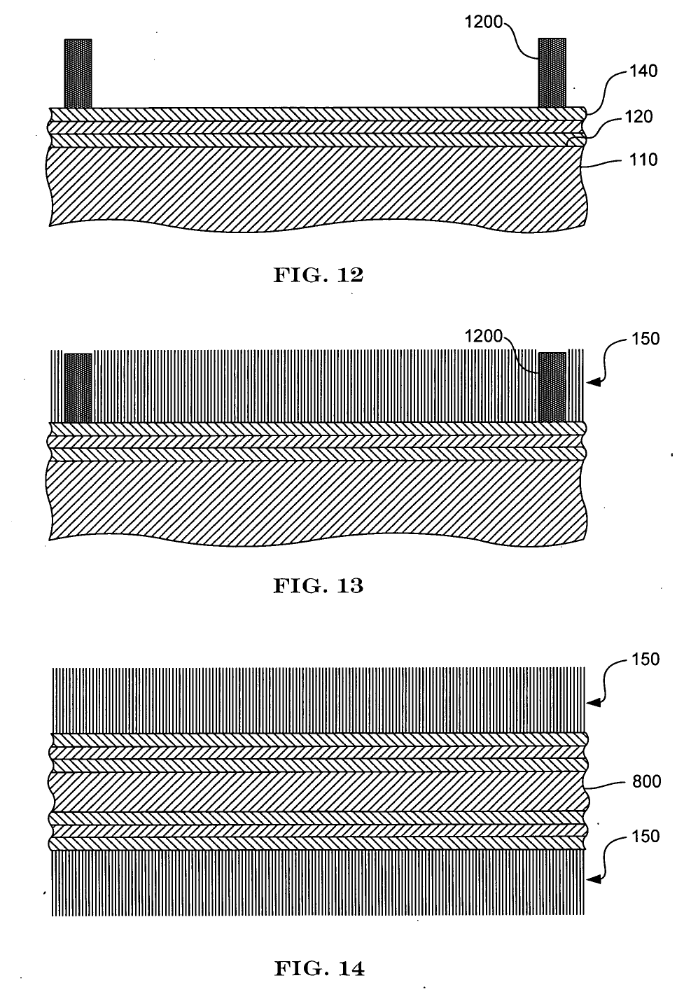

FIG. 14 illustrates that the method can also be used to provide an array 150 on both surfaces of a foil 800. In these embodiments the method can be applied to one surface and then the other, or to both surfaces simultaneously. Additionally, each of the several layers 125, 130, 140 can be formed first on one surface and then on the other, while the two arrays 150 are then grown simultaneously. A thermal pad formed by this method advantageously includes approximately twice the thickness of carbon nanotubes after an equivalent processing time.

As the foil 800 requires some form of support, a frame (not shown) can be used, for example, to support the foil 800 having a catalyst layer 140 on both surfaces within a reaction chamber while arrays 150 of carbon nanotubes are synthesized on both surfaces. Similarly, as noted above in connection with FIG. 4, arrays 150 can be formed on multiple surfaces of other substrates such as the heat spreader 400. In some embodiments multiple arrays 150 on a substrate are formed sequentially while in other embodiments the arrays 150 are formed simultaneously.

Another variation on the method performs the steps in a continuous fashion on the foil 800. In these embodiments the foil 800 is initially wound on a spool. One end of the foil 800 is fed into a guide that provides support to the foil 800 while a transport mechanism carries the foil 800 through a series of sequential processes to form the various layers 125, 130, 140, the array 150, and any subsequent layers such as attachment layer 810. This variation can be used to form the array 150 on only one side of the foil 800 or both sides, as in FIG. 14. The foil 800, once fully processed, can be sectioned to form individual thermal pads or wound onto another spool. In other embodiments, only the layers 125, 130, 140 are formed on the foil 800 in the described manner, then the foil 800 is cut into sections or coupons, and these sections or coupons are individually or batch processed to form arrays 150 thereon.

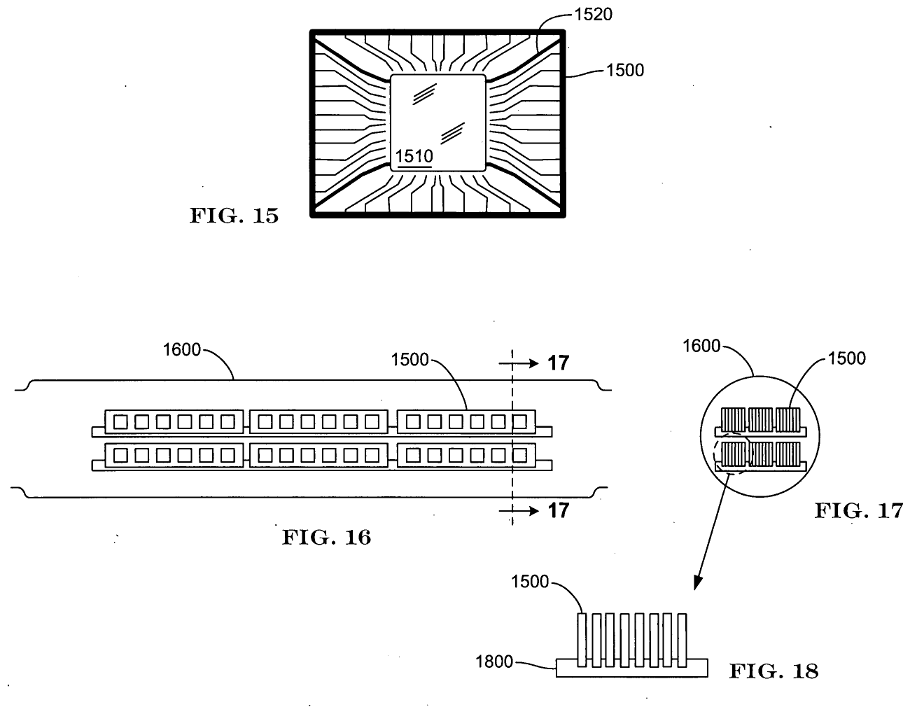

FIG. 15 shows yet another alternate substrate for carrying out the method. In FIG. 15 a lead frame 1500 serves as the substrate. The lead frame 1500 includes a die bonding pad 1510 and support fingers 1520 that attach the die bonding pad 1510 to the remainder of the lead frame 1500 which can include a plurality of other identical die bonding pads 1510. Thus, an array 150 can be formed on each pad 1510 of the lead frame 1500 by the method described above. In some embodiments, the lead frame 1500 is made of oxygen free high conductivity copper. A suitable thickness for a lead frame 1500 is about 250μ, though thinner and thicker ones can be used. After processing to form the array 150, the die bonding pad 1510 with the array 150 thereon can be separated from the remainder of the lead frame 1500 by detaching the pad 1510 from the support fingers 1520. In other embodiments, the die bonding pad 1510 is supported on a pedestal during processing and the pedestal heats the die bonding pad 1510 from beneath, for example, by inductive heating. It will be appreciated that these same heating techniques can also be applied to other embodiments described herein.

Various steps involved in forming the layers on the die bonding pads 1510 can require elevated temperatures. In some embodiments, an electric current, on the order of tens of amps, is applied across the die bonding pad 1510 in order to heat the die bonding pad 1510 during various deposition steps such as forming the array 150. The electric current can be applied to the die bonding pad 1510 through probes that contact either ends of die bonding pad 1510 or close by on the support fingers 1520.

FIGS. 16-18 illustrate an exemplary arrangement of a plurality of lead frames 1500 within a furnace 1600 for chemical vapor processing (CVD) to produce arrays 150. FIG. 16 shows a cross-section through the furnace 1600, FIG. 17 shows a cross-sectional view of the furnace 1600 taken along the line 17-17 in FIG. 16, and FIG. 18 shows an enlarged view of a portion of FIG. 17 to show the lead frames supported in a boat 1800. An exemplary furnace 1600 is a 5-inch thermal CVD system configured such that a carbon-containing gas can enter from one end of the furnace 1600, react to form the arrays 150 on the lead frames 1500, and exit the opposite end of the furnace 1600.

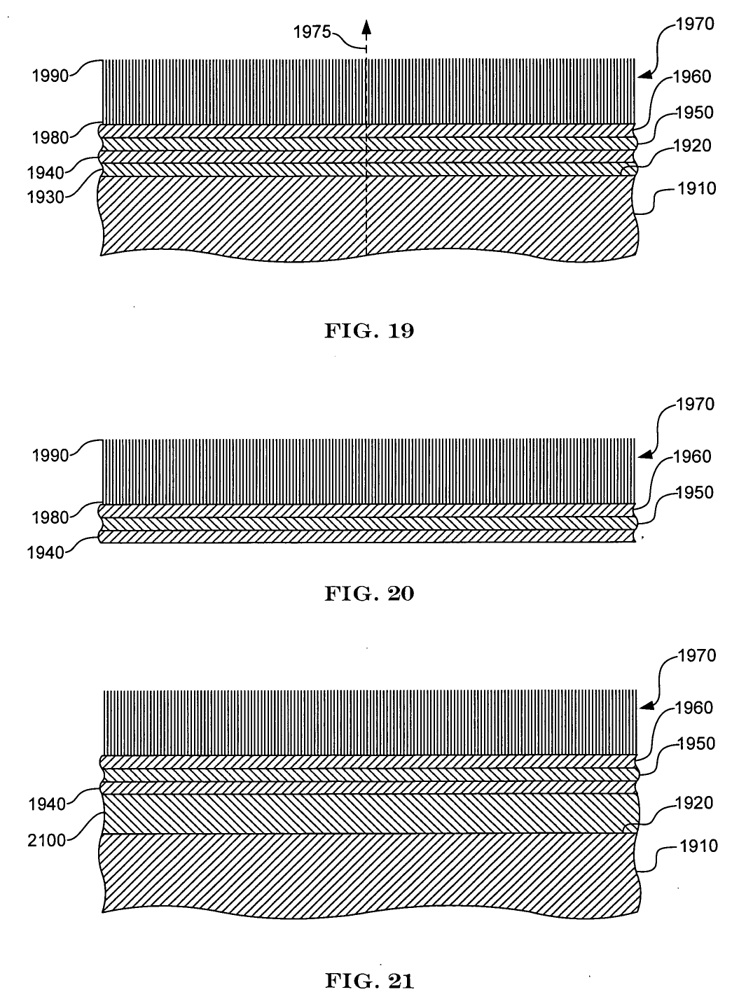

FIGS. 19-25 are directed to further methods for forming thermal pads where the substrate on which the thermal pad is formed is ultimately separated from the thermal pad rather than becoming an integral part of the thermal pad as in the prior embodiments. As used herein, a “free-standing” thermal pad is defined as a sheet-like structure having two opposing external surfaces and including an array of vertically aligned carbon nanotubes having two opposing sides. A free-standing thermal pad, as used herein, can have one of three basic structures. In a first structure, both sides of the carbon nanotube array define the external surfaces of the thermal pad. In a second structure, one side of the carbon nanotube array defines one external surface of the thermal pad and a surface layer over the opposing side of the array defines the other external surface of the thermal pad. In a third structure, surface layers over both sides of the array define both external surfaces of the thermal pad. In the second and third structures, the thickness of any surface layer, as measured from the side of the array to the external surface, is less than 1 mm and preferably less than about 500μ.

FIGS. 19 and 20 illustrate an exemplary method of forming a free-standing thermal pad. As shown by FIG. 19, a substrate 1910 with a generally planar surface 1920 is initially provided. Next, a separation layer 1930 is formed on the planar surface 1920. The method can also include forming an optional barrier layer 1940 either before or after forming the separation layer 1930. An optional interface layer 1950 is formed over the separation layer 1930, and over the barrier layer 1940, if present.

Next, a catalyst layer 1960 is formed. The catalyst layer 1960 can be formed either directly on the separation layer 1930, on the barrier layer 1940, or on the interface layer 1950. After the catalyst layer 1960 has been formed, an array 1970 of carbon nanotubes is formed on the catalyst layer 1960. The array 1970 is formed such that the carbon nanotubes are generally aligned in a direction 1975 perpendicular to the planar surface 1920. The array 1970 includes a first end 1980 attached to the catalyst layer 1970 and a second end 1990 opposite the first end 1970.

Examples of a suitable substrate 1910 include polished silicon and gallium arsenide wafers. Either can provide an atomically smooth planar surface 1920 on which to form the successive layers 1930-1970. An example of a suitable separation layer 1930 is nickel oxide. A nickel oxide separation layer 1930 can be formed by depositing and then passivating a nickel thin film to form a dense and continuous oxide film. The passivation can be achieved, for instance, by thermal oxidation, exposure to an oxygen plasma, or by exposure to a strong acid such as chromic acid. A suitable thickness for the nickel oxide separation layer 1930 is about 100 Å.

Another suitable separation layer 1930, where the substrate 1910 is gallium arsenide, is aluminum arsenide. An aluminum arsenide separation layer 1930 can be formed, for example, by metal oxide CVD (MOCVD), and a suitable thickness for such a film is about 500 Å. As an alternative to forming the separation layer 1930 by deposition, the separation layer 1930 can be formed by ion implantation into the substrate 1910. For example, hydrogen ions can be implanted into silicon to form a silicon hydride layer than can readily delaminate from the silicon.

The purpose of the barrier layer 1940 is to prevent diffusion between the substrate 1910 and/or the separation layer 1930 and the catalyst layer 1960. Preventing such diffusion is desirable in those embodiments where either the substrate 1910 or the separation layer 1930 includes one or more elements that can poison the catalyst of the catalyst layer 1960 and prevent nanotube growth. It will be appreciated that barrier layer 1940 is essentially the same in these embodiments as barrier layer 125 described in detail above and can be formed in these embodiments of the materials and by the methods provided.

The interface layer 1950 is provided, where needed, to improve the catalyst layer 1960 which, in turn, provides for higher quality nanotubes characterized by higher wall crystallinities and fewer defects. Interface layer 1950 is essentially the same in these embodiments as interface layer 130 described in detail above. Likewise, catalyst layer 1960 and array 1970 are essentially the same in these embodiments as catalyst layer 140 and array 150 described in detail above. Both the interface layer 1950, the catalyst layer 1960, and the array 1970 can be formed in these embodiments of the materials and by the methods provided above for interface layer 130, catalyst layer 140, and the array 150.

After the carbon nanotube array 1970 has been formed, the thermal pad is removed from the substrate 1910 at the separation layer 1930, as shown in FIG. 20. It will be appreciated that the surface of the thermal pad, after release from the substrate 1910, will be essentially as smooth as the surface of the substrate 1910 on which the array 1970 was formed, and therefore can be atomically smooth, or nearly so. As described below, further processing of the array 1970 can occur either before or after separation from the substrate 1910.

Separation can be accomplished mechanically, chemically, or through a combination of techniques. For instance, where the separation layer comprises nickel oxide and an adjoining layer includes copper, separation can occur by the application of a shear force. Some embodiments take advantage of differences in the coefficients of thermal expansion between the array 1970 and the separation layer 1930. In these embodiments, after the array 1970 is formed and begins to cool, the mismatch in the coefficients of thermal expansion causes a stress to develop along the interface that can cause the array 1970 to spontaneously detach, or to detach upon the application of very little force.

An adhesive tape can be applied to the second end 1990, in some embodiments, to both pull the array 1970 away from the separation layer 1930 and to give the released thermal pad a backing layer. In some embodiments the adhesive tape becomes part of the completed thermal pad. In these thermal pads, suitable adhesive tapes can be either electrically insulating, such as with a Kapton backing, or metallized to be conductive, to allow the thermal pad to either electrically isolate a device or component, or provide a path to ground.

Alternatively, the separation layer 1930 can be removed chemically by wet etching or a thermal treatment. Thermal treatments take advantage of differences in coefficients of thermal expansion between layers to cause delamination at the separation layer 1930. Wet etching can be achieved with strong acids such as hydrofluoric acid to dissolve either silicon or silicon dioxide. For some applications less aggressive and more environmentally acceptable solvents are desirable. Water, for instance, can be used where the separation layer 1930 comprises a water-soluble salt.

As shown in FIG. 21, another exemplary method includes a surface layer 2100 intended to become part of the finished thermal pad after separation from the substrate 1910. In FIG. 21, the surface layer 2100 can be a thin layer of copper, for example. The particular material for the surface layer 2100 can be chosen with respect to the intended use of the thermal pad. For instance, a metal for the surface layer 2100 can be chosen to provide a superior bond to the material to which the thermal pad will be joined, or to match the coefficient of thermal expansion to that material. Zinc and silicon carbide are two examples of materials for the surface layer 2100 where the thermal pad is to be attached to a silicon surface. Nickel and aluminum can be used for the surface layer 2100 where the thermal pad will be joined to a nickel or aluminum coating on the surface of a thermal management aid (i.e., a heat sink or heat spreader).

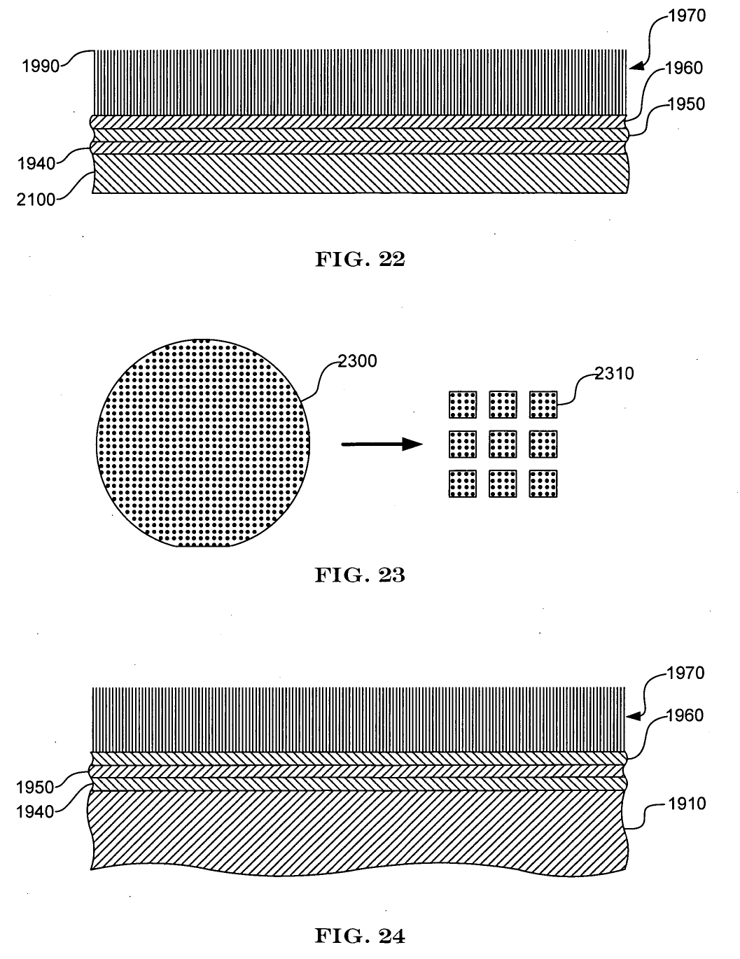

In the example of FIG. 21, compared to that in FIGS. 19 and 20, the surface layer 2100 is substituted for the separation layer 1930 and the thermal pad is separated from the substrate 1910 by dissolving the substrate 1910, as shown in FIG. 22. For example, where the substrate 1910 is a thinned silicon wafer, an acid such as hydrofluoric acid (HF) can be used to etch away the silicon, leaving the free-standing thermal pad bounded on one side by a smooth copper film. It will be appreciated that the surface layer 2100 can also be added into the embodiment illustrated by FIG. 19. For instance, the surface layer 2100 can be included between the separation layer 1930 and the catalyst layer 1960. In some of these embodiments, the surface layer 2100 can also serve as a barrier layer 1940.

Although the method of FIGS. 21 and 22 can produce a free-standing thermal pad, in some embodiments the free-standing thermal pad is never realized. Instead, the second end 1990 is attached to a surface of another object such as a foil or a thermal management aid prior to the dissolution of the substrate 1910. Methods for attaching the second end 1990 to other objects are discussed further below.

In some of the embodiments represented generally by FIGS. 19-22, the substrate 1910 is diced into sections or coupons before the thermal pad is separated from the substrate 1910. FIG. 23 illustrates a top view of a wafer 2300, including an array 1970, and coupons 2310 produced by dicing the wafer 2300. With respect to the embodiments of FIGS. 19 and 20, dicing can occur prior to separating the thermal pad from the substrate 1910. With respect to the embodiments of FIGS. 21 and 22, dicing can occur before the substrate 1910 is dissolved. It will be understood that “dicing” is a term of art in the semiconductor field that is specific to cutting semiconductor wafers; however, the concept illustrated here is more general. Accordingly, a substrate 1910 other than a semiconductor wafer can also be segmented prior to separating the substrate 1910 from the thermal pad or before dissolving the substrate 1910. Metal substrates 1910 can be die cut, for example.

Yet another method for forming free-standing carbon nanotube thermal pads is illustrated in FIGS. 24 and 25. In FIG. 24 an array 1970 is formed on a substrate 1910 in a manner analogous to that shown by FIGS. 19 and 21, but without either the separation layer 1930 or the surface layer 2100. After the array 1970 has been grown to the desired height, the environment (e.g., within a furnace or reactor) is modified to stop the growth of the carbon nanotubes and to etch the carbon nanotubes at the first end 1980 of the array 1970. More specifically, the process chemistry in the environment is changed by eliminating the gaseous carbon source to stop the growth process, and by introducing another gas that preferentially etches the carbon nanotubes at the interface with the catalyst layer 1960.

An example of such a gas is a mixture of water vapor and hydrogen gas. In one embodiment, the array 1970 is grown in a tube furnace. 50 standard cubic centimeters per minute (sccm) of argon gas is bubbled through a water bubbler to saturate the argon with water vapor. The argon saturated with water vapor is then mixed with 400 sccm of hydrogen gas and introduced into the tube furnace which is maintained at a temperature of 700° C. This atmosphere is maintained in the tube furnace for 5 minutes and causes the thermal pad to lift off of the substrate 1910, as shown in FIG. 25.

The array 1970 in any of the above embodiments shown in FIGS. 19-25 can be further processed either prior to, or after, release from the substrate 1910 according to the methods illustrated above with respect to FIGS. 6-13.

FIGS. 1-14, and 20, 22, and 25 as shown or as further modified by the processes of FIGS. 6-13, also represent different embodiments of finished thermal pads. The thermal pads are generally thin in a vertical dimension, direction 155 in FIG. 1, and bounded by two generally parallel surfaces of essentially arbitrary dimensions that are perpendicular to the vertical dimension. One advantage of these thermal pads is that the width, depth, and overall shape of the thermal pads (i.e., as viewed normal to the two parallel surfaces) can be established through well known manufacturing techniques of the semiconductor industry such as masking and etching, or by cutting the desired shape from a larger sheet. Exemplary thermal pads have surface areas measured perpendicular to the vertical dimension ranging from about 1 mm×1 mm, or less, to over 6″×6″. Arrays of nanotubes can have thicknesses ranging from a few microns to over 1 mm. A preferable thickness range is from 0.1 mm to 2 mm.

In the above discussion, the arrays have been described as having two ends. As an array forms a sheet with two sides within a thermal pad, it will be understood that an end of the array is used herein interchangeably with a side of a sheet. Either end of an array may form a surface of a thermal pad, or either or both ends can be capped so that the ends are not exposed and another material defines the surface. In those thermal pads characterized by a surface other than an exposed end of the array, the material that defines the surface can be a thin substrate or foil, or a metal layer that is either unfinished, polished, or polished and planarized. Additionally, any of these thermal pads can include carbon nanotubes grown in bundles, where the bundles are separated from each other to allow the bundles to bend when compressed. Also, any of these thermal pads can include spacers.

Any of these thermal pads can also include a matrix material that fills the interstitial space between the ends of the array. Similarly, any can include a base metal layer that only partially fills the interstitial space of the array around the carbon nanotubes at the first end. Also, the interstitial space of any of these thermal pads can be left empty. As noted above, keeping the interstitial space empty improves flexibility. It should also be noted that keeping the interstitial space empty also improves compliance of the thermal pad to differential thermal expansion between opposing surfaces of two objects. The flexibility and pliability of some thermal pads allows them to be attached to curved surfaces in addition to generally flat surfaces.

Some thermal pads are fixedly attached to an inflexible substrate, such as a heat spreader, where the free surface of the thermal pad is meant to be attached to the surface of some other object. Other such thermal pads are free-standing components meant to be disposed between the opposing surfaces of a heat source and a heat sink.

A thermal pad having exposed nanotubes as one surface can be joined by that surface to a surface of an object through the use of a low melting point metal or eutectic alloy or a solder. One advantage of this method of joining the thermal pad to the surface of the other object is that neither surface is required to be particularly smooth. Irregularities in either are filled by the low melting point metal, eutectic alloy, or solder. Reworking can be easily accomplished by low temperature heating.

A thermal pad having exposed nanotubes as one surface can also be joined to a surface of an object simply by pressing the two together, known herein as “dry-pressing.” Dry pressing can be accomplished with or without the application of pressure and/or heat. Modest elevated temperatures (e.g. 200-300° C.) and pressures (e.g., 10 to 100 psi) can be used. In some embodiments, sufficient heat is applied to soften or melt the surface of the object, for example, the copper surface of a heat sink, so that the ends of the carbon nanotubes push into the surface. In these embodiments it can be advantageous to perform the dry-pressing in a non-oxidizing environment such as an oxygen-free atmosphere. Dry-pressing can also comprise making the ends of the carbon nanotubes temporarily reactive. Here, plasma etching can be used, for example, to etch away amorphous carbon and/or any catalyst materials. Plasma etching can also create reactive dangling bonds on the exposed ends of the carbon nanotubes that can form bonds with the opposing surface. Dry pressing can also comprise anodic bonding, where a strong electric field pulls ions from the interface to create a strong bond.

In those thermal pads where a surface is defined by a thin substrate, a foil, an unfinished metal layer, or a polished metal layer, that surface can be joined to a surface of another object in several ways. One method is to join the two surfaces with a metal having a melting point below that of the materials that define the opposing surfaces. For example, silver can be used to join a copper heat spreader with a palladium metal layer of a thermal pad. Lower melting point metals such as indium and solder can also be used. In some embodiments the low melting point metal is cleaned with an acid such as hydrochloric acid to remove the native oxide. In the case of a thin substrate 200 comprising silicon, the silicon surface can be metallized with titanium and then silver to bond well to the low melting point metal.

In other instances, where both the surface of the object and the exposed surface of the thermal pad are very smooth, the two can be held together by van der Waals attractions. In still other instances, both the surface of the object and the surface of the thermal pad are compositionally the same or very similar, for example where both comprise silicon. In this example, Si—Si bonds can spontaneously form between the two surfaces.

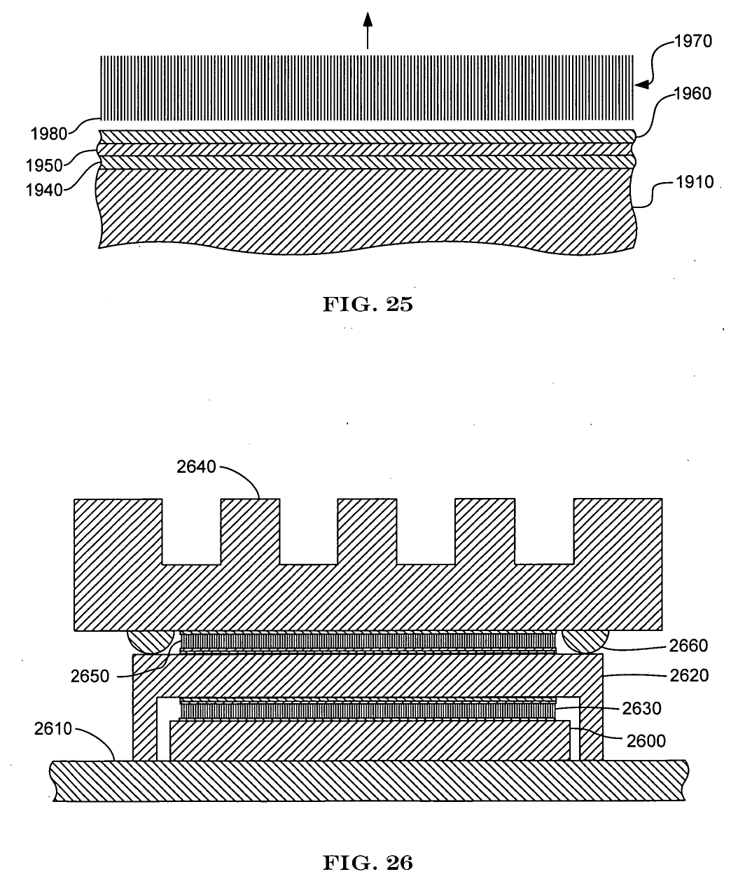

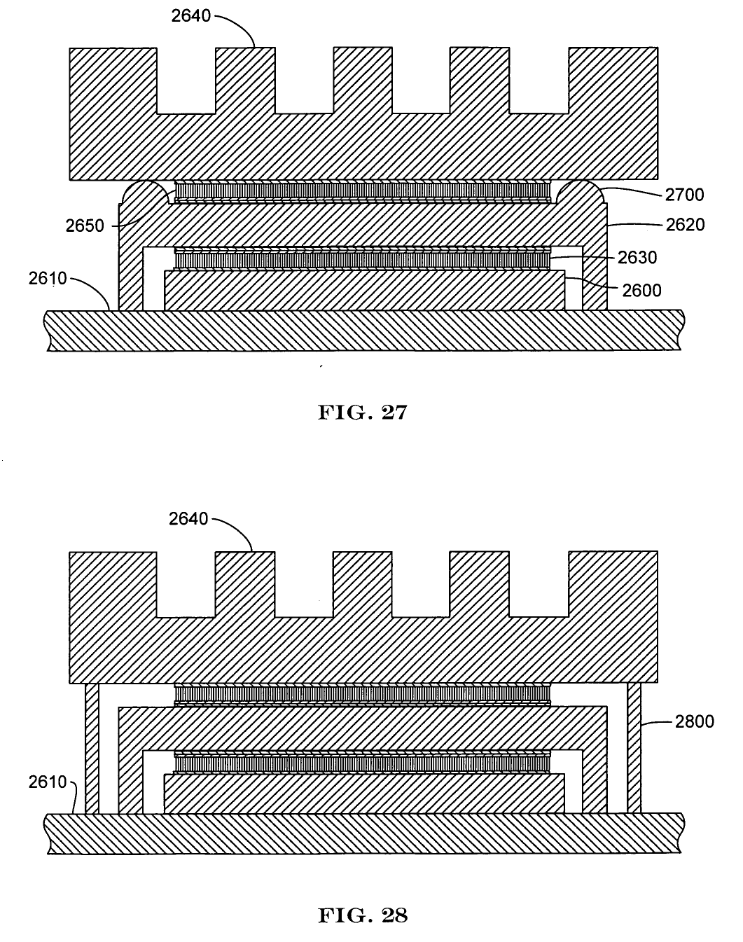

FIGS. 26-32 relate to devices that incorporate carbon nanotube thermal pads and methods for their assembly. FIG. 26 shows a package including a semiconductor die 2600 mounted to a substrate 2610, such as a printed circuit board (PCB), and joined to a heat spreader 2620 by a first thermal pad 2630, and a heat sink 2640 joined to the heat spreader 2620 by a second thermal pad 2650. Stand-offs 2660 can be blocks that are bonded between the heat spreader 2620 and the heat sink 2640 during assembly of the package. Alternately, the stand-offs 2600 can be integral with the heat sink 2640. Stand-offs 2600 can also comprise springs, pogo pins, and the like. The height of the stand-offs 2660 should be slightly less than a thickness of the thermal pad 2650 to allow the thermal pad 2650 to be compressed during assembly, but should also be thick enough so that the stand-offs 2660 prevent the thermal pad 2650 from being damaged by overloading. FIG. 27 shows the same package as in FIG. 26 with stand-offs 2700 that are integral with the heat spreader 2620.

Stand-offs 2800 can also be placed between the heat sink 2640 and the substrate 2610, as shown in FIG. 28. As above, the stand-offs 2800 can be integral with the heat sink 2640. And as above, the height of the stand-offs 2800 should be such that the thermal pads 2630, 2650 can absorb some compression without being damaged by overloading. Stand-offs 2800 can be used in conjunction with stand-offs 2660. Stand-offs 2800 are also useful in those embodiments that do not include a heat spreader 2620 and have only a single thermal pad between the heat sink 2640 and the semiconductor die 2600.

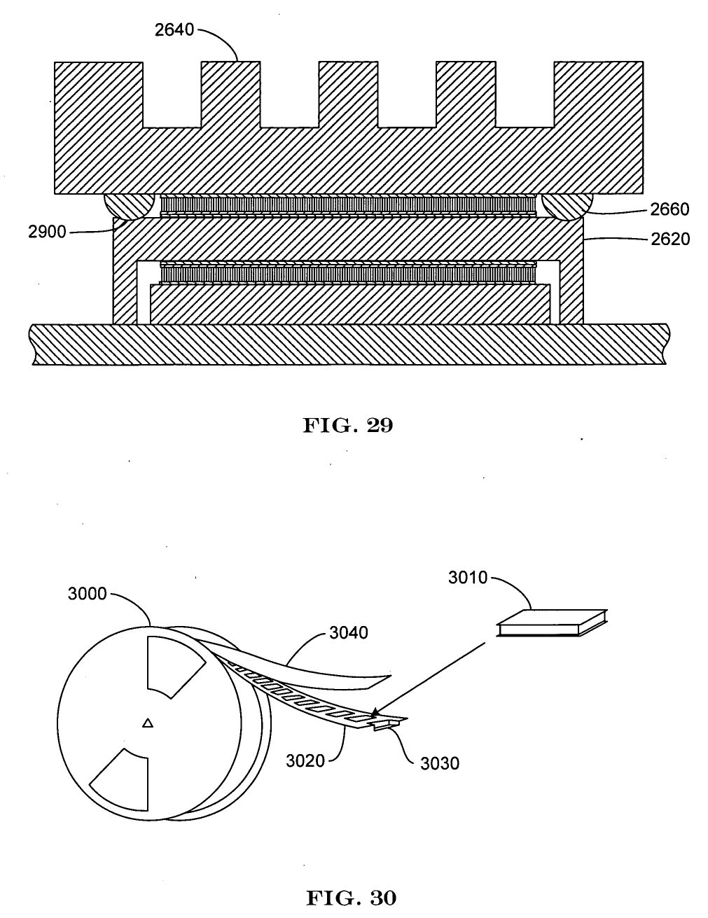

Still another variant is shown in FIG. 29. Here, the heat spreader 2620 includes depressions 2900 configured to receive the stand-offs 2660. In some embodiments, the depressions 2900 can help with the alignment of the of the heat spreader 2620 with the heat sink 2640. The depressions 2900 can be sized to be slightly larger than the mating stand-offs 2660 to accommodate manufacturing tolerances. In some embodiments, the depressions 2900 are filled with a self-curing, or UV curable, resin or resilient polymer before assembly.

FIG. 30 shows a perspective view of a spool 3000 of thermal pads 3010 for automated tape bonding. The spool 3000 includes a carrier tape 3020 including a series of embossed cavities 3030 sized to hold a thermal pad 3010. A pressure sensitive cover tape 3040 covers the carrier tape 3020 to hold the thermal pads 3010 in the embossed cavities 3030. Thermal pads on substrates as well as free-standing thermal pads can be conveniently packaged in spools 3000 for later use. In particular, such a spool 3000 can be used with well known automated taping machines.

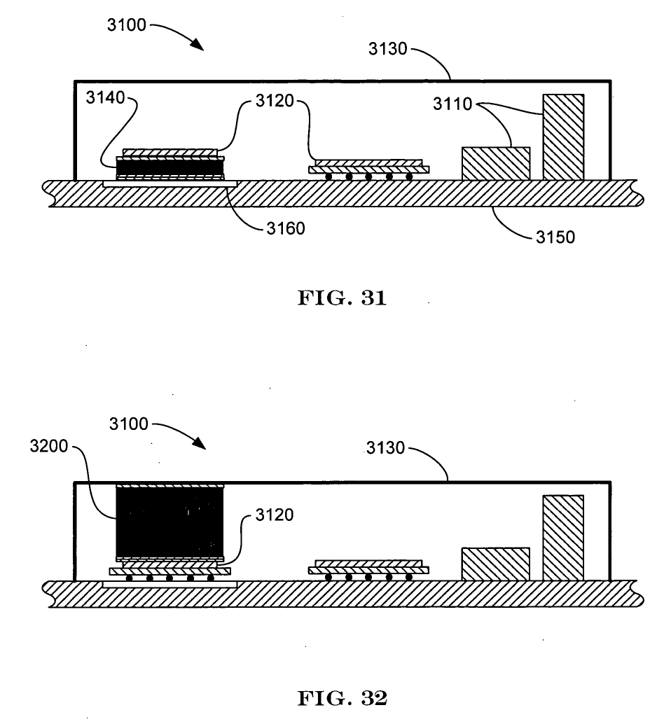

FIGS. 31 and 32 relate to the application of thermal pads to the class of small footprint mobile consumer products that include such devices as cell phones, PDAs, and laptops. In these applications power dissipation is critical yet difficult to achieve. In particular, these products tend to have severe space constraints and there is typically room for only a single circuit card. In FIG. 31, a small footprint mobile consumer product 3100 includes both passive components 3110 and active components 3120, such as an RF amplifier and a digital signal processor (DSP), disposed within an electromagnetic interference (EMI) enclosure 3130. In this example, a thermal pad 3140 is disposed as a pedestal between an active component 3120 and a circuit card 3150. More specifically, the thermal pad 3140 can be attached to a coined area 3160 of the circuit card 3150.

FIG. 32 shows a similar design for the small footprint mobile consumer product 3100. In this example, a thermal pad 3200 thermally connects the active component 3120 with the EMI enclosure 3130. Accordingly, the EMI enclosure 3130 becomes a heat sink for the product 3100.

In the foregoing specification, the invention is described with reference to specific embodiments thereof, but those skilled in the art will recognize that the invention is not limited thereto. Various features and aspects of the above-described invention may be used individually or jointly. Further, the invention can be utilized in any number of environments and applications beyond those described herein without departing from the broader spirit and scope of the specification. The specification and drawings are, accordingly, to be regarded as illustrative rather than restrictive. It will be recognized that the terms “comprising,” “including,” and “having,” as used herein, are specifically intended to be read as open-ended terms of art.

What is claimed is:

1. An electronic device comprising:
a semiconductor die;
a heat spreader;
a first thermal pad disposed between the semiconductor die and the heat spreader aid;
a heat sink;
a second thermal pad disposed between the heat sink and the heat spreader; and
a spacer disposed between the heat sink and the heat spreader.

2. The device of claim 1 further comprising a substrate beneath the semiconductor die and a spacer between the substrate and the heat sink.

3. The device of claim 1 wherein the spacer is integral with the heat spreader.

4. The device of claim 1 wherein the spacer is integral with the heat sink.

5. The device of claim 4 wherein the heat spreader includes a recess engaged with the spacer.

6. An electronic device comprising:
a heat source;
a thermal management aid; and
a thermal pad disposed between the heat source and the thermal management aid,
the thermal pad including
a sheet of vertically aligned carbon nanotubes,
a silicon layer between the sheet and the heat source, and
a metal layer between the sheet and the thermal management aid.

7. The electronic device of claim 6 wherein the metal layer includes copper.

8. The electronic device of claim 6 wherein the silicon layer and the heat source are joined together by van der Waals attractions.

9. The electronic device of claim 6 further comprising an adhesive layer between the metal layer and the thermal management aid.

10. The electronic device of claim 9 wherein the adhesive layer is electrically insulating.

11. The electronic device of claim 6 wherein the interstitial space between the carbon nanotubes of the sheet is substantially unfilled.

12. An electronic device comprising:
a semiconductor die formed of a semiconducting material;
a thermal management aid; and
a thermal pad disposed between the heat source and the thermal management aid,
the thermal pad including
a sheet of vertically aligned carbon nanotubes having first and second sides, the ends of the carbon nanotubes of the first side extending at least partially into the thermal management aid, and
a layer between the second side of the sheet and the semiconductor die, the layer also formed of the semiconducting material.

13. A mobile device comprising:
an active component;
an EMI enclosure; and
a thermal pad including a sheet of vertically aligned carbon nanotubes providing thermal communication between the active component and the EMI enclosure.

14. The mobile device of claim 13 wherein the active component comprises an RF amplifier.

15. The mobile device of claim 13 wherein the active component comprises a digital signal processor.

16. A method for making an electronic device comprising:
receiving a thermal pad on a carrier tape from a spool of thermal pads, the thermal pads including an array of generally aligned carbon nanotubes; and
bonding the thermal pad between a semiconductor die and a thermal management aid.

17. The method of claim 16 wherein bonding the thermal pad includes plasma etching a surface of the array.

18. The method of claim 16 wherein bonding the thermal pad includes anodic bonding of a surface of the thermal pad to either the semiconductor die or the thermal management aid.

19. The method of claim 16 wherein bonding the thermal pad includes dry pressing the thermal pad to the thermal management aid.

20. A method for making an electronic device comprising:
bonding a first side of a thermal pad to a thermal management aid, the thermal pad including an array of generally aligned carbon nanotubes disposed on a substrate;
separating the substrate from a second side of the thermal pad after bonding the first side; and
bonding the second side of the thermal pad to a semiconductor die.
